(19) United States
(12) Patent Application Publication
(10) Pub. No.: US 2016/0322526 A1
(43) Pub. Date: Nov. 3, 2016

(54) PHOTOVOLTAIC CELL, PHOTOVOLTAIC MODULE AS WELL AS THE PRODUCTION AND USE THEREOF

(71) Applicant: FRAUNHOFER-GESELLSCHAFT ZUR FÖRDERUNG DER ANGEWANDTEN FORSCHUNG E.V., München (DE)

(72) Inventors: Tilmann Kuhn, Hinterzarten (DE); Helen Rose Wilson, Freiburg (DE)

(21) Appl. No.: 15/104,818

(22) PCT Filed: Dec. 17, 2014
(86) PCT No.: PCT/EP2014/078317

§ 371 Date: Jun. 15, 2016

(30) Foreign Application Priority Data
Dec. 20, 2013 (DE) 10 2013 226 943.9
Jan. 21, 2014 (DE) 10 2014 200 956.1

(51) Int. Cl. H01L 31/05; H01L 31/0224; H01L 31/0352; H01L 31/02

(52) U.S. Cl. CPC H01L 31/0504; H01L 31/02008; H01L 31/022441; H01L 31/035281; H01L 31/0352

(57) ABSTRACT

A photovoltaic cell may be provided that includes flat semiconductor substrates, each having a front face and a rear face, where at least one front face contact is arranged on the front face and at least one rear face contact is arranged on the rear face. Each semiconductor substrate may form a subarea of the photovoltaic cell and the semiconductor substrates may be electrically connected to one another in parallel, where the semiconductor substrates are arranged at a distance from one another, and at least two semiconductor substrates have a different shape and/or size. A photovoltaic module equipped with the photovoltaic cell may be provided, and to a method for producing the photovoltaic cell may be provided.

### CROSS-REFERENCE TO RELATED APPLICATIONS

This application is a 371 nationalization of PCT/EP2014/078317, entitled “PHOTOVOLTAISCHE ZELLE, PHOTOVOLTAIKMODUL SOWIE DESSEN HERSTELLUNG UND VERWENDUNG,” having an international filing date of Dec. 17, 2014, the entire contents of which are hereby incorporated by reference, which in turn claims priority under 35 USC §119 to German patent application DE 10 2014 200 956.1 filed on Jan. 21, 2014, entitled “Photovoltaische Zelle, Photovoltaikmodul sowie dessen Herstellung and Verwendung,” the entire contents of which are hereby incorporated by reference.

### TECHNICAL FIELD

The invention relates to a photovoltaic cell which has a semiconductor substrate having a front face and a rear face, wherein at least one front face contact is arranged on the front face and at least one rear face contact is arranged on the rear face. The invention further relates to a photovoltaic module including a plurality of photovoltaic cells, to a method for producing a photovoltaic cell and to a building or a façade element having such a photovoltaic module.

### BACKGROUND

It is known from the art to produce photovoltaic cells from semiconductor material. The photovoltaic cell consists substantially of a flat p-n-diode which is provided with front and rear face contacts. The front face contacts usually cover only a subarea of the semiconductor material, as a result of which sunlight can penetrate the semiconductor material. The electron-hole pairs which are formed when light is absorbed drift to the front face or rear face and can be tapped as electric voltage via the front face contacts and the rear face contacts. Such photovoltaic cells can be used e.g. for the electric energy supply of a building.

In particular when used in transparent solar modules, these known photovoltaic cells have the drawback that Moire effects can occur on the surface of the photovoltaic cells and can confuse a person looking at a building façade equipped therewith. Finally, the known photovoltaic cells and modules produced therefrom offer limited esthetic design options.

### BRIEF DESCRIPTION OF THE DRAWINGS

FIG. 1 shows a first method step for producing a photovoltaic cell;

FIG. 2 shows a second method step for producing a photovoltaic cell;

FIG. 3 shows a third method step for producing a photovoltaic cell;

FIG. 4 explains a method step for producing a first embodiment of a photovoltaic module according to the invention;

FIG. 5 explains a further method step for producing a photovoltaic module according to the invention;

FIG. 6 shows a first alternative embodiment of the photovoltaic cell according to the invention;

FIG. 7 shows a second alternative embodiment of the photovoltaic cell according to the invention;

FIG. 8 shows different semiconductor substrates;

FIG. 9 shows a first production step for producing the semiconductor substrates;

FIG. 10 shows a second method step for producing the semiconductor substrates;

FIG. 11 shows a third method step for producing the semiconductor substrates;

FIG. 12 shows a fourth method step for producing the semiconductor substrates;

FIG. 13 shows a fifth method step for producing the semiconductor substrates;

FIG. 14 shows a cross-section through a photovoltaic cell according to the invention;

FIG. 15 shows a first application example of the photovoltaic modules according to the invention;

FIG. 16 shows a second application example of the semiconductor modules according to the invention;

FIG. 17 shows a third application example of the semiconductor modules according to the invention;

FIG. 18 shows a second embodiment of a photovoltaic module according to the invention;

FIG. 19 shows a section of a first embodiment of a photovoltaic module according to the invention;

FIG. 20 shows a section of a third embodiment of a photovoltaic module according to the invention;

FIG. 21 shows a section of a fourth embodiment of a photovoltaic module according to the invention;

FIG. 22 shows a section of a fifth embodiment of a photovoltaic module according to the invention;

FIG. 23 shows a sixth embodiment of the photovoltaic module according to the invention in axonometry;

FIG. 24 shows a section of an alternative embodiment of semiconductor substrates; and

FIG. 25 shows a seventh embodiment of a photovoltaic module according to the invention.

### DETAILED DESCRIPTION

Proceeding from this prior art, an object of the invention to provide a photovoltaic cell which offers more diverse design options and is pleasant to look at.

According to the invention, the object is solved by a photovoltaic cell according to claim 1, a photovoltaic module according to claim 12, a building according to claim 16 and a method for producing a photovoltaic cell according to claim 17.

It is proposed according to the invention to compose the photovoltaic cell from a plurality of flat semiconductor substrates, each having a front face and a rear face. By contrast, photovoltaic cells known to date always use a single semiconductor substrate having a front face and an opposite rear face.

At least one pn junction is formed parallel to the front face and/or rear face by doping the semiconductor substrate, and it is at this junction where sunlight which impinges thereon is absorbed. The resulting electron-hole pairs drift to the front face or rear face respectively and can be tapped as electric voltage or electric current via the appropriate contacts.

According to the invention, it has now been found that an individual photovoltaic cell does not necessarily have to be formed from a single flat semiconductor substrate. The photovoltaic cell according to the invention is rather made from a plurality of semiconductor substrates, each of which forms a subarea of the photovoltaic cell. The individual subareas or sub-cells of the photovoltaic cell are electrically connected to one another in parallel. As a result, the electric current formed by the respective subareas adds up whereas the electric voltage remains constant.

Each individual semiconductor substrate from a plurality of flat semiconductor substrates carries a front face contact on the front face thereof and a rear face contact on the rear face thereof. In each case, the front face contact only occupies a subarea of the semiconductor substrate, as a result of which other subareas remain uncovered to allow the penetration of sunlight. In some embodiments of the invention, a plurality of the front face contacts can be available which can be formed e.g. as thin contact fingers or contact lines. Therefore, the resulting electric current can be tapped more effectively since the drift lengths of the minority charge carriers in the semiconductor substrate for reaching the front face contact are smaller.

The rear face contact can also only cover a subarea of the rear face of the semiconductor substrate and can also be formed as thin contact fingers or contact lines. In other embodiments of the invention, the rear face contact can also be applied over the entire area so as to yield a complete or almost complete metallization of the rear faces of the semiconductor substrates.

In some embodiments of the invention, the semiconductor substrate can have at least one bore by means of which the front face contacts can be connected in an electrically conductive way to connecting elements on the rear face. As a result, it is possible to minimize shadowing of the front face by the power rails.

In some embodiments of the invention, the front face contacts and the rear face contact can be applied in generally known manner by screen printing, aerosol printing or pad printing or by the deposition of thin metal layers in vacuo. In some embodiments of the invention, the contacts can be reinforced by electroplating to improve the current load capacity. The material of the front and rear face contacts is usually selected on the basis of the material of the semiconductor substrate and the doping thereof in such a way that ohmic contacts result. In some embodiments of the invention, the contacts can contain or consist of silver, gold or copper.

The semiconductor substrate as such can contain a direct semiconductor material or an indirect semiconductor material. In some embodiments of the invention, the semiconductor substrate can consist of silicon or contain silicon. In addition, the semiconductor substrate can contain dopants to render possible a predeterminable electric conductivity. Furthermore, the semiconductor substrate can contain conventional contaminations. In some embodiments of the invention, the semiconductor substrate can be crystalline. In some embodiments of the invention, the semiconductor substrate can be amorphous. In some embodiments of the invention, the semiconductor substrate can have a thickness of about 50 μm to about 1000 μm or a thickness of about 100 μm to about 500 μm.

In some embodiments of the invention, the photovoltaic cell can have a plurality of power rails, the longitudinal extensions of which run along a first spatial direction and which enclose together with a longitudinal extension of the front face contacts an angle of about 20° to about 90° or an angle of about 45° to about 90° or an angle of about 80° to about 90°. The stated angular ranges here merely refer to the magnitudes, and therefore the angle between the longitudinal extension of the front face contacts and the longitudinal extension of the power rails can be marked off in a positive or negative direction.

Due to this geometry, the plurality of power rails takes care that the current of different subareas of the photovoltaic cell distributes along the longitudinal extension of the power rails. The front face contacts extending approximately orthogonal thereto distribute the current in a direction orthogonal to the longitudinal extension of the power rails, and therefore all front face contacts of all semiconductor substrates are connected to one another via the power rails and the front face contacts of adjacent semiconductor substrates. In an equal way, the rear face contacts of all semiconductor substrates are electrically connected to one another. Therefore, compensating currents can flow along the longitudinal extension of the power rails and via the rear face contacts also in a direction orthogonal thereto. This serves to achieve in an easy way the parallel connection of the subareas of the photovoltaic cell according to the invention.

The photovoltaic cells according to the invention can be joined in a generally known manner to give a photovoltaic module. Therefore, the photovoltaic cells according to the invention should not be mistaken for a known photovoltaic module which also contains a plurality of photovoltaic cells but where each cell only has a single semiconductor substrate.

In some embodiments of the invention, each power rail is connected in an electrically conductive fashion to each other power rail of the corresponding side via at least one front face contact or at least one rear face contact. An electrically conductive connection shall here be understood to mean a direct current coupling between the power rails for the purposes of the present invention.

In some embodiments of the invention, each power rail with the exception of the peripheral power rails can be connected to at least two front face contacts or at least two rear face contacts of different semiconductor substrates. This is equivalent to a geometry where different semiconductor substrates or subareas of the photovoltaic cell overlap in a direction orthogonal to the longitudinal extension of the power rails.

In some embodiments of the invention, at least two semiconductor substrates from the plurality of flat semiconductor substrates of a photovoltaic cell can have a different shape and/or size. The effect of this feature is that irregular, non-periodic structures can be realized which virtually prevent moire effects from occurring.

In some embodiments of the invention, the first power rails and the second power rails can be arranged approximately parallel to one another, the first and second power rails being offset relative to one another in a direction orthogonal to the longitudinal extension of the power rails. This serves to prevent the first and second power rails from causing a short circuit in subareas where no semiconductor substrate is located.

In some embodiments of the invention, the plurality of flat semiconductor substrates can consist of an equal material. In some embodiments of the invention, the plurality of flat semiconductor substrates can consist of the same material. If the individual semiconductor substrates consist of an equal material, they produce an equal electric voltage when irradiated with light, such that a parallel connection of the subareas of the photovoltaic cells is possible without large output currents flowing between the individual semiconductor substrates. Furthermore, the cell voltage is defined by the selection of the semiconductor material. Nevertheless, it is possible to use semiconductor materials from different production charges or offcuts from semiconductor production, which have to be discarded thus far. As a result, the crystalline semiconductor material, which is produced in an energy-intensive way, can be utilized more efficiently.

In some embodiments of the invention, the semiconductor substrates can be provided with coatings having different colors to extend the design options of the photovoltaic cell. Such a coating can contain or consist of silicon nitride of varying thickness, as a result of which the coating acts as an interference filter and gives an intense color effect without influencing the cell voltage.

In other embodiments of the invention, the semiconductor substrates can consist of the same material by cutting all semiconductor substrates out of a single wafer. The cutting can be done e.g. by laser cutting or machining.

In some embodiments of the invention, a photovoltaic cell can contain segments which are not connected electrically to the power rails and/or which are made from an insulating material and have at least one front face contact and/or at least one rear face contact which is electrically connected to at least two power rails. The additional use of segments which are not electrically connected to the power rails, can serve to fill subareas of the photovoltaic cell with material which gives an optical impression which is approximately equal to that of the semiconductor substrate. As a result, the esthetic appearance of the photovoltaic cell can be adapted to different requirements. Segments made from an insulating material and having a front face contact and/or a rear face contact, can be inserted in sites where no photovoltaically active semiconductor substrate is provided which requires a current flow between different power rails to make possible the desired parallel connection of the individual semiconductor substrates.

In some embodiments of the invention, the plurality of flat semiconductor substrates of each photovoltaic cell can have an equal surface area. It is thus ensured that different photovoltaic cells supply an equal electric current in spite of different appearance and different total area. Here, the total area is considered to be the sum of the areas of the semiconductor substrates and the intermediate spaces. This makes possible a low-loss series connection of different photovoltaic cells within a photovoltaic module. In other embodiments of the invention, cells made from different materials can be interconnected to one another and all supply the same current. For this purpose, the respective active surface of the cells can be adapted in such a way that materials having a small current yield have larger surface areas than materials with higher current yield.

In some embodiments of the invention, the power rails can be embedded in an embedding film. This serves to considerably facilitate the handling regarding the assembly or production of the photovoltaic cells according to the invention when photovoltaic modules are produced. In some embodiments of the invention, the embedding film can have an adhesive layer and/or can be sealed with the semiconductor substrates to produce the photovoltaic cell according to the invention.

The invention shall be explained in more detail below by means of drawings without limiting the general inventive concept, wherein:

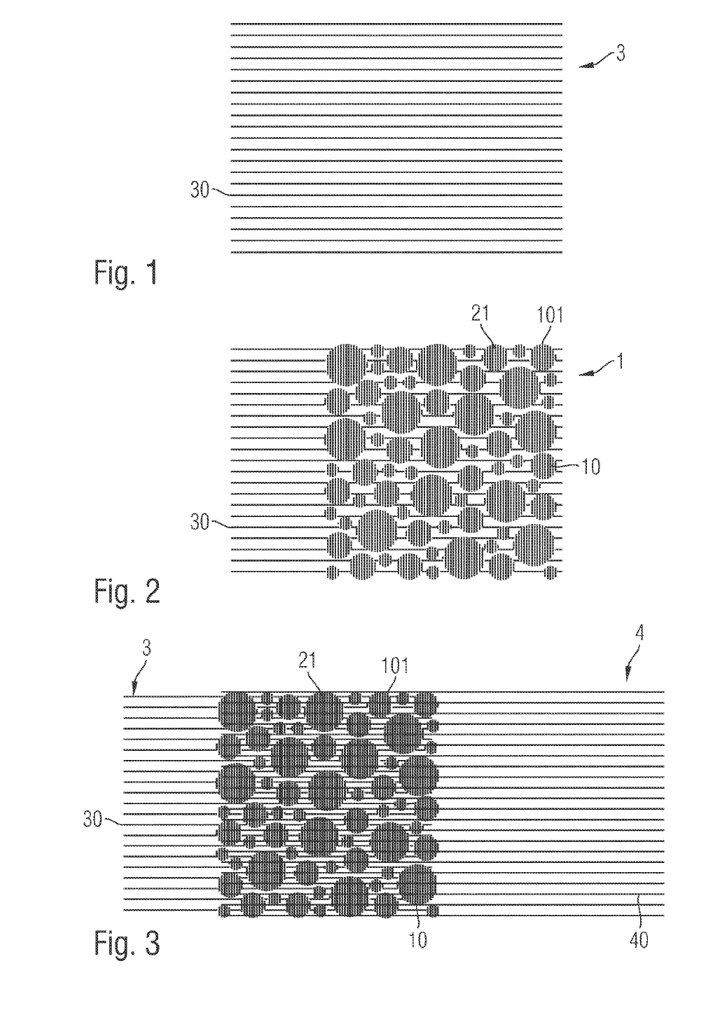

FIG. 1 shows a first method step for producing a photovoltaic cell.

FIG. 2 shows a second method step for producing a photovoltaic cell.

FIG. 3 shows a third method step for producing a photovoltaic cell.

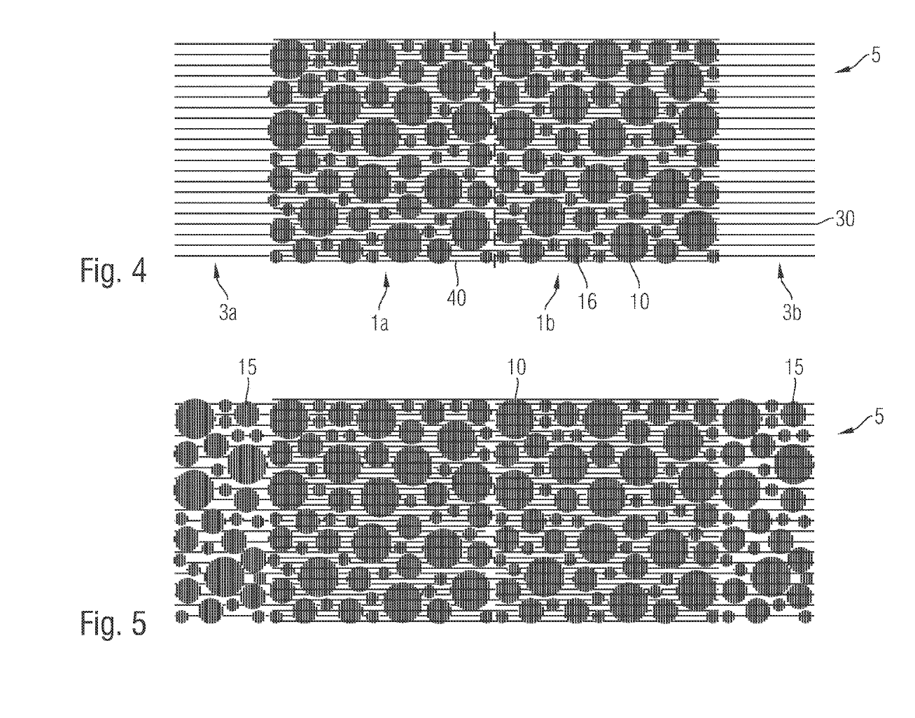

FIG. 4 explains a method step for producing a first embodiment of a photovoltaic module according to the invention.

FIG. 5 explains a further method step for producing a photovoltaic module according to the invention.

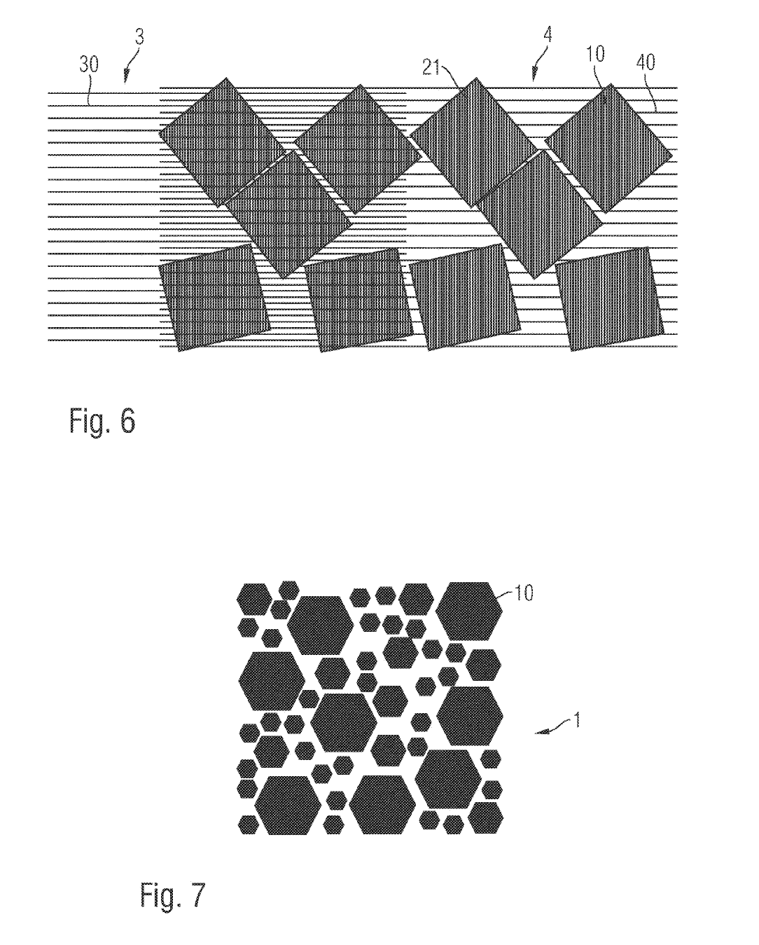

FIG. 6 shows a first alternative embodiment of the photovoltaic cell according to the invention.

FIG. 7 shows a second alternative embodiment of the photovoltaic cell according to the invention.

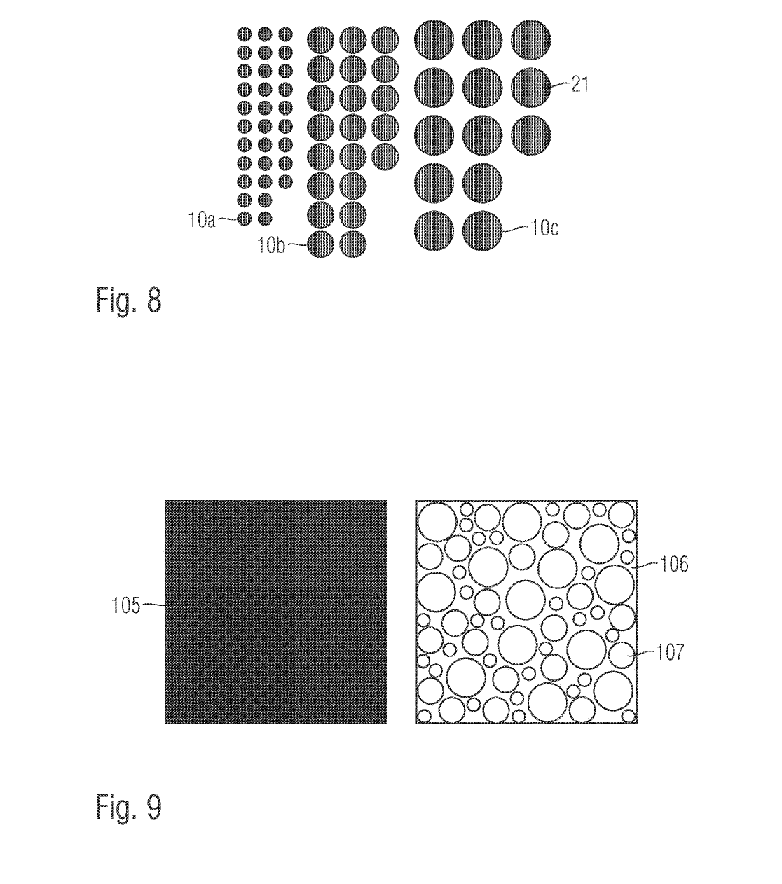

FIG. 8 shows different semiconductor substrates.

FIG. 9 shows a first production step for producing the semiconductor substrates.

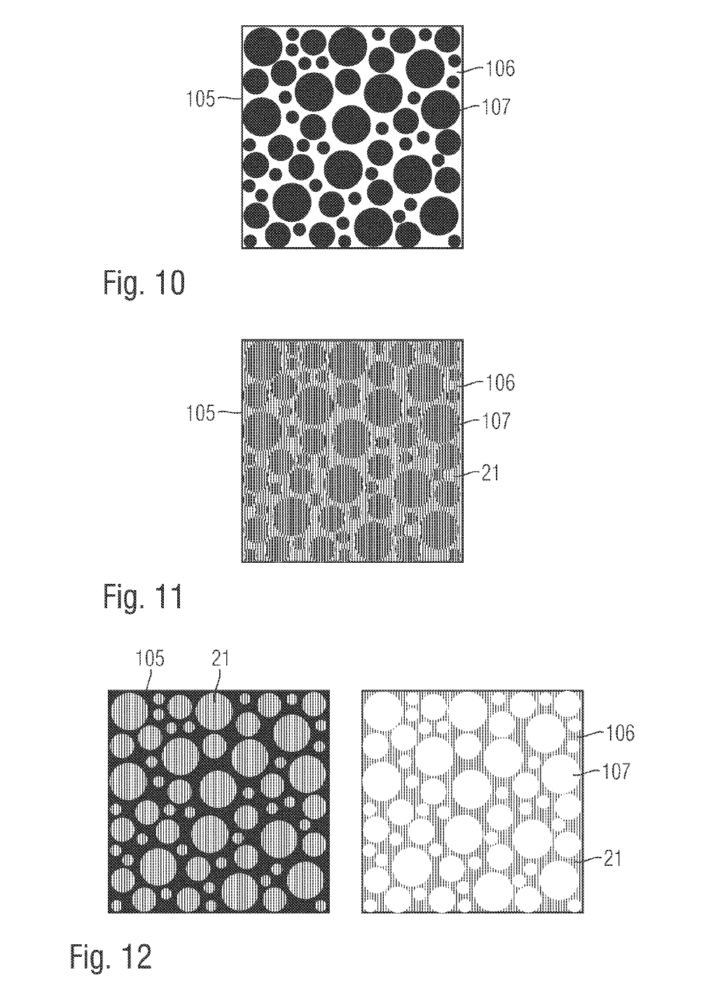

FIG. 10 shows a second method step for producing the semiconductor substrates.

FIG. 11 shows a third method step for producing the semiconductor substrates.

FIG. 12 shows a fourth method step for producing the semiconductor substrates.

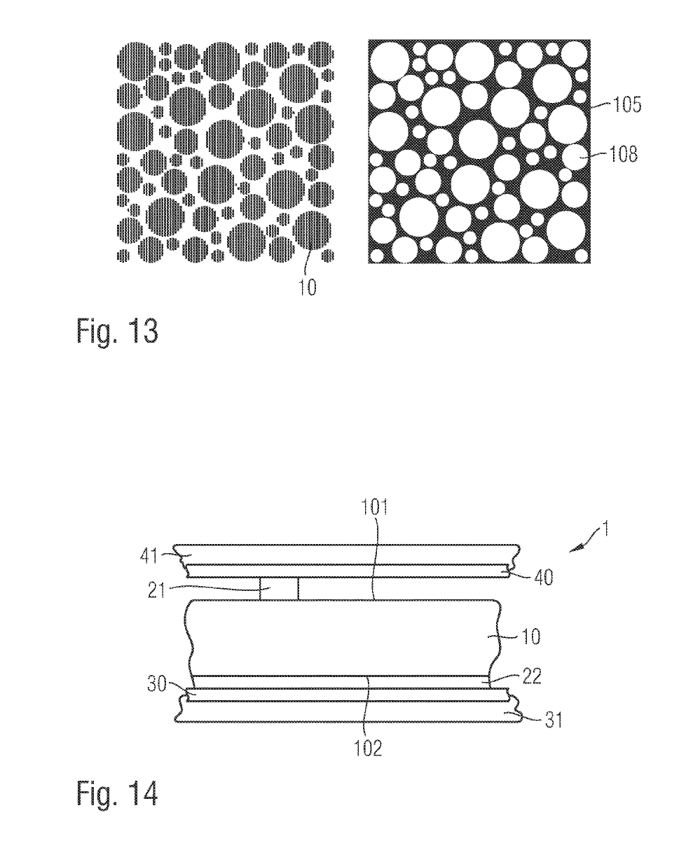

FIG. 13 shows a fifth method step for producing the semiconductor substrates.

FIG. 14 shows a cross-section through a photovoltaic cell according to the invention.

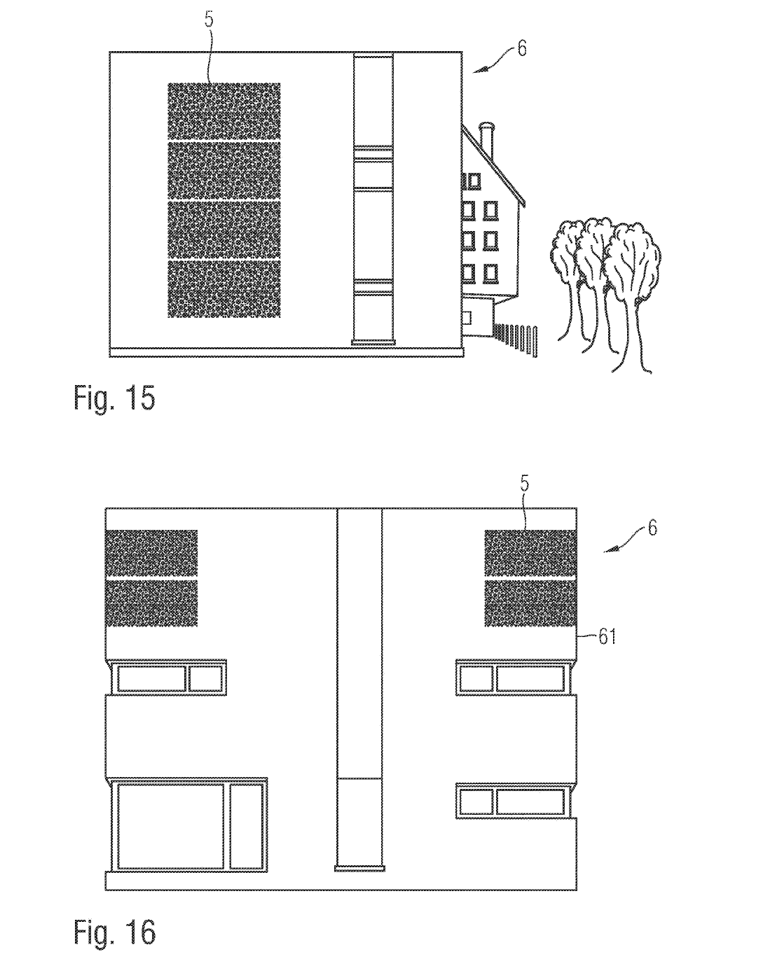

FIG. 15 shows a first application example of the photovoltaic modules according to the invention.

FIG. 16 shows a second application example of the semiconductor modules according to the invention.

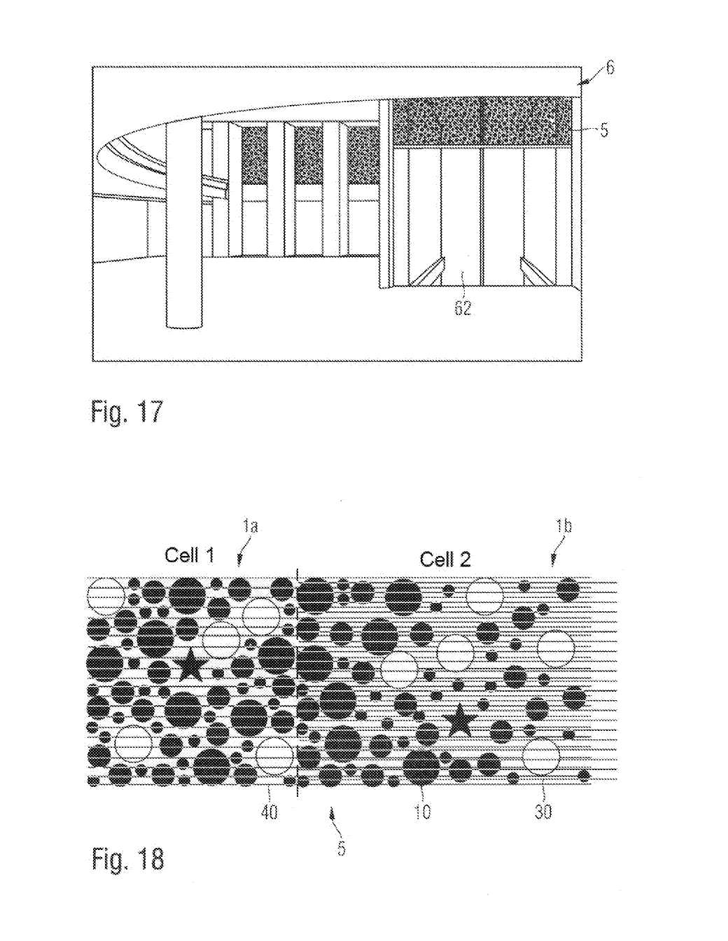

FIG. 17 shows a third application example of the semiconductor modules according to the invention.

FIG. 18 shows a second embodiment of a photovoltaic module according to the invention.

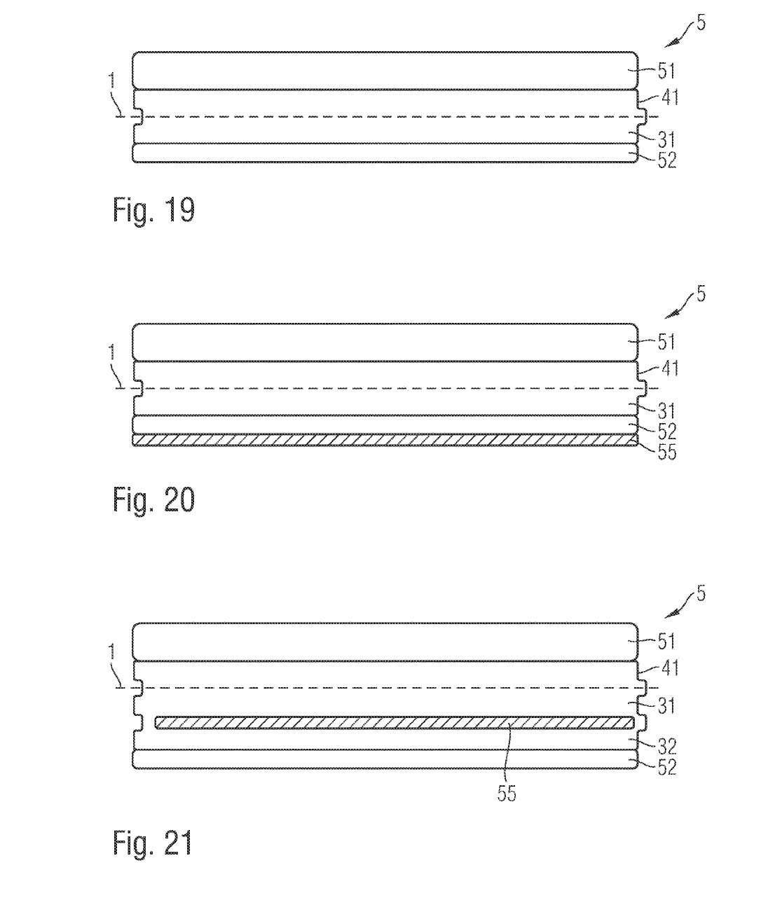

FIG. 19 shows a section of a first embodiment of a photovoltaic module according to the invention.

FIG. 20 shows a section of a third embodiment of a photovoltaic module according to the invention.

FIG. 21 shows a section of a fourth embodiment of a photovoltaic module according to the invention.

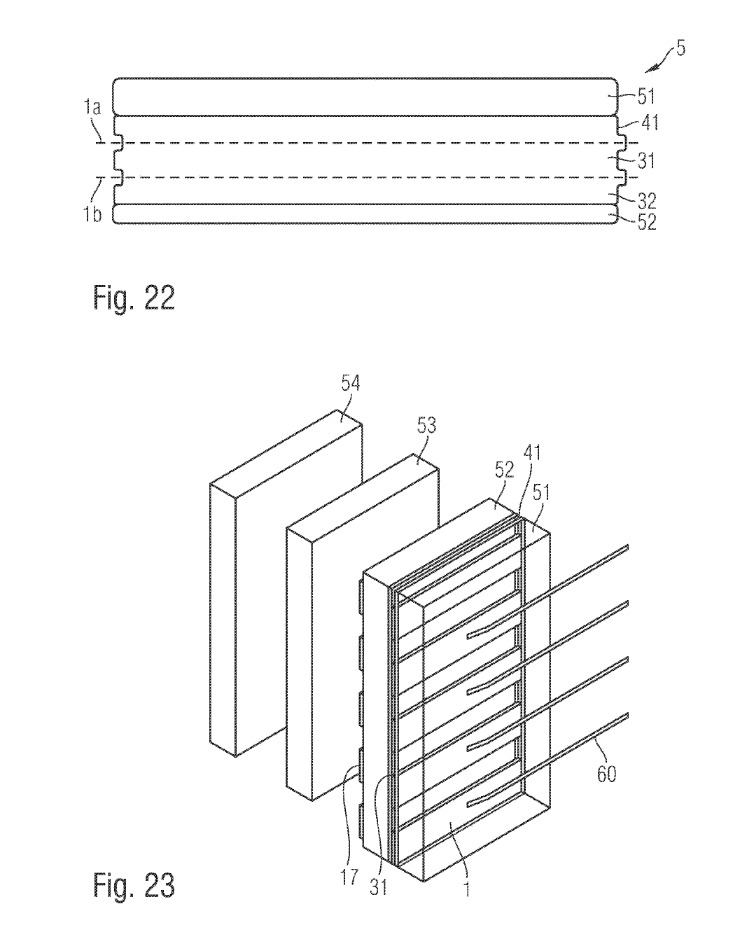

FIG. 22 shows a section of a fifth embodiment of a photovoltaic module according to the invention.

FIG. 23 shows a sixth embodiment of the photovoltaic module according to the invention in axonometry.

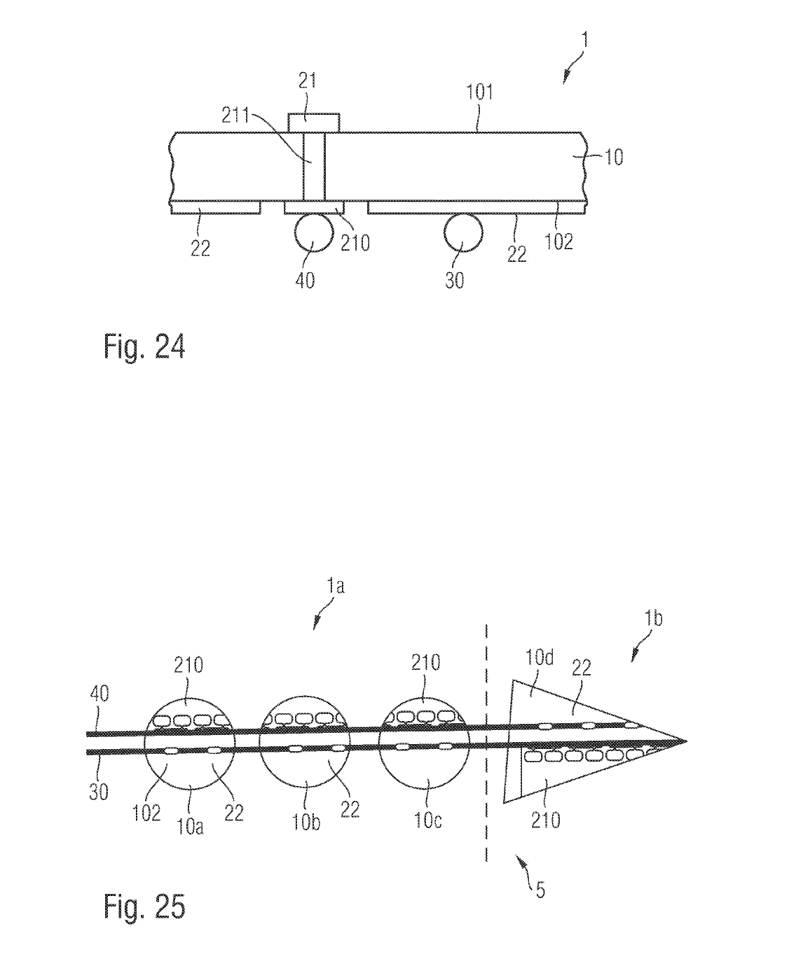

FIG. 24 shows a section of an alternative embodiment of semiconductor substrates.

FIG. 25 shows a seventh embodiment of a photovoltaic module according to the invention.

A possible production method of the photovoltaic cell according to the present invention is explained by means of FIGS. 1 to 3. FIGS. 4 and 5 explain the possible further processing of the photovoltaic cell into a photovoltaic module comprising a plurality of photovoltaic cells.

In the first method step, a plurality 3 of second power rails 30 is provided, as shown in FIG. 1. The power rails 1 can be made e.g. as wires with round or polygonal cross-section. The diameter of the power rails 30 can be between about 0.1 mm and about 1 mm. In some embodiments of the invention, the power rails 30 can contain or consist of gold, silver, aluminum or copper. The distance of two adjacent power rails 30 can be between about 1 mm and about 50 mm or between about 1 mm and about 10 mm. In order to simplify the handling, a plurality of power rails 30 can be received in an embedding film 31, as explained in more detail below by means of FIG. 14.

FIG. 2 shows how to apply a plurality of semiconductor substrates 10 via the rear face contacts 22 thereof to the plurality 3 of power rails 30 in the second method step. In some embodiments of the invention, an electrically conductive connection between the power rails 30 and the rear face contacts 22 can be obtained by soldering, spot-welding or by electrically conductive adhesives. As a result, a mechanical attachment can simultaneously be achieved between the power rails 30 and the semiconductor substrates 10. In other embodiments of the invention, the mechanical attachment of the semiconductor substrates 10 can also be made by adhering or sealing it to the embedding film. A separate, firmly bonded connection of the rear face contacts to the power rails 30 can be omitted in this case.

As is shown in FIG. 2, the semiconductor substrates 10 of a single photovoltaic cell 1 can have different sizes. The individual semiconductor substrates 10 can be arranged in a regular or an irregular pattern within the photovoltaic cell 1. Furthermore, FIG. 2 shows that at least the front face contacts 21 of the semiconductor substrates 10 have a strip-like structuring. As a result, the front face contacts 21 only occupy a subarea of each semiconductor substrate 10 and a part of the front face 101 is available for the light access into the semiconductor substrates 10.

FIG. 2 shows that the longitudinal extension of the front face contacts 21 extends approximately orthogonal to the longitudinal extension of the power rails 30. This ensures that there is an electric parallel connection of all semiconductor substrates 10 of a photovoltaic cell 1. The electric potential along the power rails 30 is compensated by the electric conductivity of the power rails 30. A potential difference between the power rails 30 can be compensated by the electrically conductive connection of the power rails to the front and/or rear face contacts via said contacts. Thus, all front faces of the semiconductor substrates 10 and all rear faces of the semiconductor substrates 10 are direct-current coupled and have a uniform electrical potential.

FIG. 3 shows the completion of the photovoltaic cell by applying a plurality 4 of first power rails 40. The first power rails 40 can also be made from a wire having a round or polygonal cross-section and are optionally fixed in an embedding film, as already specified above by means of the second power rails 3. The first power rails 40 are provided to contact the front face contacts 21 of the semiconductor substrates 10. Since most of the power rails 40 contact at least two front face contacts of at least two different semiconductor substrates 10, the first power rails 40 are also connected to one another in conductive fashion, as a result of which they have an equal electric potential and yield the parallel connection of the semiconductor substrates 10 according to the invention.

In order to avoid a short circuit between the first power rails 40 and the second power rails 30, it is possible to arrange the first and second power rails offset to one another. As a result, the second power rails are arranged in the gaps between two first power rails and the first power rails are arranged in the gaps between two second power rails.

FIG. 4 shows the further processing of the photovoltaic cell 1 into a first embodiment of a photovoltaic module 5. For this purpose, a plurality of semiconductor substrates 10 can be applied via the respective rear face contacts to the first power rails 4 of the preceding photovoltaic cell. Then, second power rails 3 can again be applied to the front face of the photovoltaic cells 10. This leads to a series connection of the adjacent photovoltaic cells within the photovoltaic module 5.

In order to make possible an efficient parallel connection of the individual semiconductor substrates within a photovoltaic cell, said semiconductor substrates can be made from an equal or the same material, as a result of which an equal cell voltage is achieved with constant illumination. In order to obtain an efficient series connection of the photovoltaic cells within the photovoltaic module, the active surface area of all semiconductor substrates processed within a photovoltaic cell can be identical, as a result of which each photovoltaic cell can supply an equal electric current when the light intensity is equal. If there are differences as regards the ability to supply current, segments 16 can be arranged in some photovoltaic cells, said segments consisting of an insulator and, like photovoltaic cells, being provided with front and rear face contacts. These segments 16 can be used to render possible a flow of the current between power rails. However, since the segments 16 per se do not supply any electric energy, the use of these segments 16 can serve to finely adapt the current supplied by the photovoltaic cell 1. In an equal way, it is also possible to insert segments 15, which consist of an insulating material when a current flow beyond the boundaries of the power rails is already ensured by the semiconductor substrates of the photovoltaic cell.

FIG. 5 shows a further method step for producing a photovoltaic module according to the invention. As shown in FIG. 5, the free ends 3a and 3b of the power rails can be covered with segments 15 made from insulating material to ensure a uniform optical appearance of the photovoltaic cell or modules made therefrom over the entire surface area thereof.

FIG. 6 shows a second embodiment of the photovoltaic cell or the photovoltaic module proposed according to the invention. Equal components are provided with equal reference signs. Therefore, the description is limited to the essential differences.

As shown in FIG. 6, the semiconductor substrates 10 have a square base instead of a round base. The photovoltaic cell according to the second embodiment also merely contains uniform semiconductor substrates having equal size. As also shown in FIG. 6, the arrangement of the front face contacts 21 is different on the individual semiconductor substrates 10 so as to ensure, even in the case of a different relative position of the semiconductor substrates 10 relative to the power rails 40 and/or 30, that the front face contacts 21 extend approximately orthogonal to the power rails 30 and 40. However, it is obviously not essential to precisely observe a right angle between the longitudinal extension of the front face contacts 21 and the longitudinal extension of the power rails 30 and 40, as long as the front face contacts contact a plurality of power rails and can provide for a potential compensation between the power rails.

FIG. 7 shows a third embodiment of the semiconductor substrates 10. According to the third embodiment, polygonal semiconductor substrates of three different sizes are used. The polygonal base according to FIG. 7 has six corners, it being, of course, also possible to use a larger or smaller number of corners. Furthermore, it is possible to use irregularly shaped polygonal basic forms. What is essential is that the sum of the surface areas of the semiconductor substrates of all photovoltaic cells within a photovoltaic module is equal. However, the division of this sum into different subareas can vary.

FIG. 8 shows once again semiconductor substrates 10a, 10 and 10c in three sizes, which can be used within a photovoltaic cell. The semiconductor substrates 10a, 10b and 10c all have round basic forms but differ in size. FIG. 8 shows by way of example first semiconductor substrates 10a, which have a small diameter, second semiconductor substrates 10b, which have a medium diameter, and third semiconductor substrates 10c, which have a large diameter.

Each semiconductor substrate 10a, 10b and 10c has a plurality of front face contacts which adopt the shape of elongate contact fingers. The front face contacts can be arranged up to close to the edge of the semiconductor substrates 10a, 10b and 10c.

However, the edge itself can remain uncovered to avoid a short circuit between front and rear face contacts.

The rear face contact can be made in an equal way as the front face contact or comprise a metallization over the entire surface area. The front and rear face contacts can be applied in generally known manner to each individual semiconductor substrate 10a, 10b and 10c, e.g. by depositing and subsequently structuring a metal layer, by a printing method or by deposition without external current or deposition using electroplating.

The round semiconductor substrates 10a, 10b and 10c can be made from a larger substrate by a cutting method, e.g. by laser cutting. In other embodiments, round starting materials or wafers can be used directly without further cutting being required.

FIGS. 9 to 13 explain in more detail an alternative manufacturing method for the semiconductor substrates 10. The manufacturing method allows a production of a plurality of semiconductor substrates 10, which requires little time.

FIG. 9 shows a basic substrate 105 as a starting material. The basic substrate 105 can be an already pre-cut, right-angled substrate or a complete wafer as known in microelectronics as a starting material. The basic substrate 105 can be doped to achieve predeterminable electric conductivities. The basic substrate 105 can already contain a fully processed pn diode which serves as a basic element for the photovoltaic cell.

FIG. 9 also shows a mask 106, which contains a plurality of recesses 107. The mask 106 can contain e.g. a film, a glass plate or a ceramic as a starting material. The recesses 107 define the subsequent position of the semiconductor substrates 10a, 10b and 10c on the basic substrate 105, which shall be used for the photovoltaic cell 1.

FIG. 10 explains how to place the mask 106 on the basic substrate 105 in such a way that the mask covers subareas of the basic substrate 105 and the recesses 107 expose subareas of the substrate.

FIG. 11 shows how to print a plurality of front face contacts 21 onto the surface of the mask 106 and the basic substrate 105 by a printing method, such as screen printing, pad printing or aerosol printing.

FIG. 12 shows the next method step, namely the removal of the mask 106 from the basic substrate 105. As shown in FIG. 12, the basic substrate 105 is only provided with the front face contacts 21 in the subareas exposed by the recesses 107. In the last method step, the semiconductor substrates 10 can be cut out of the basic substrate 105 by a cutting method. For example, laser cutting is suitable for producing any free forms of the semiconductor substrates 10. Having concluded this method step, what is left is a basic substrate 105, which has a plurality of holes 108 and can be used either as a mask for the production of a further plurality of semiconductor substrates 10 or can be discarded.

If the outer contour of the semiconductor substrates 10, which is defined by the cutting guide, is slightly larger than the contour of the recesses 107, it can be ensured that an edge is left around the front face contacts 21 and can reliably prevent a short circuit between front face contact and rear face contact.

FIG. 14 shows the cross-section through a photovoltaic cell according to FIG. 3.

The middle part of FIG. 14 shows a semiconductor substrate 10. The semiconductor substrate 10 has a front face 101 and an opposite rear face 102. A plurality of front face contacts 21 is arranged on the front face 101. However, the section in FIG. 14 only shows a single front face contact 21. The front face contact 21 can be made as a metallization of a subarea on the front face 101.

A rear face contact 22 is disposed on the rear face 102. In the illustrated embodiment, the rear face contact 22 is formed by a metallization over the entire area. However, the rear face contact 22 can also have a structuring as described by means of the front face contact 21.

The rear face contact 22 is in contact with second power rails 30. The second power rails 30 are embedded in an embedding film 31. Here, only a part of the cross-section of the power rails 30 is received in the embedding film 31, as a result of which a metallic surface area of the power rail 30 is exposed in the direction of the rear face contact 22.

In addition, the embedding film 31 can be provided with an adhesive layer to both contact the power rails 30 with the rear face contact 22 and render possible a mechanically robust combination between the power rails and the semiconductor substrates 10 by applying and pressing on the embedding film 31.

In an equal way, first power rails 40 are received in an embedding film 41. The first power rails 40 are placed on the first face 101 of the semiconductor substrate 1, as a result of which these rails contact the front face contacts 21. At least the embedding film 41 can be transparent or translucent, such that sunlight impinges on the first face 101 of the semiconductor substrates 10 when the photovoltaic cell is operated.

FIG. 15 shows an application example of a photovoltaic module 5 according to the invention. The photovoltaic module 5 is arranged on a façade 6. The assembly can either be made in generally known manner by back-ventilated holders so as to avoid a heat buildup in the semiconductor substrates 10. In other embodiments of the invention, the photovoltaic module 5 can be an integral component of a façade element which is placed in front of the building 6. As a result, it is possible to both create the façade and install the photovoltaic system in a single work step.

FIG. 15 shows a building façade which is made in natural stone or other mineral building materials.

FIG. 16 shows a further use of the present invention. FIG. 16 also shows a building 6 having a façade element 61, which contains the photovoltaic module 5 according to the invention. The façade element 61 according to FIG. 16 can be made of wood or wood materials.

FIG. 17 explains the integration of the photovoltaic modules 5 according to the invention into a window element 62 of a building 6. Since the semiconductor substrates 10 do not occupy the entire surface area of the photovoltaic cells 1, light can penetrate between individual semiconductor substrates 10. As a result, the subareas of the windows 62 covered with the photovoltaic modules continue to be translucent, as a result of which a light incidence into the building is still possible. Depending on the covering density with semiconductor substrates 10, it can still be possible to look out of the window 62.

FIG. 18 shows a second embodiment of a photovoltaic module according to the invention. Two photovoltaic cells 1a and 1b are shown by way of example. In other embodiments of the invention, the number of photovoltaic cells 1 in the photovoltaic module 5 can be larger.

Each photovoltaic cell 1a and 1b is composed of a plurality of semiconductor substrates 10, which are interconnected in parallel to one another via first power rails 40 and second power rails 30, whereas the first cell 1a and the second cell 1b form an electric series connection.

As shown in FIG. 18, the semiconductor substrates 10 of the first cell 1a are arranged relative to each other at a comparatively small relative distance. The semiconductor substrates 10 of the second cell 1b have a larger distance from one another, as a result of which the second cell 1b occupies a larger total area. The total area is here considered to be the sum of the areas of the semiconductor substrates and the intermediate spaces. Nevertheless, the active area, i.e. the sum of the areas of the respective semiconductor substrates 10, of the first cell 1a and of the second cell 1b, is equal. This leads to the same electric parameters, namely current and voltage, thus rendering possible a series connection of the two photovoltaic cells 1a and 1b without any problems.

The varying gross area of the photovoltaic cells 1a and 1b renders possible different design options on a façade. For example, the illusion of a leaking or melting photovoltaic module 5 can be obtained on the edges thereof. Photovoltaic modules which are known to date and have identical photovoltaic cells always have geometrically defined, usually straight edges. Furthermore, the photovoltaic cell 1b can be used with a larger gross area in the region of light bands or window openings to thus render possible the access of light into the building or the unobstructed inhabitants' view from the building. In other surface areas of the façade, the photovoltaic cell 1a renders possible a larger energy output per area element on account of the denser coverage thereof with semiconductor substrates 10.

FIG. 19 shows a section of the first embodiment of the photovoltaic module according to the invention. The photovoltaic module 5 has a cover glass 51, which is provided for the access of solar energy. An upper embedding film 41 and a lower embedding film 31, which embed the photovoltaic cells 1, are disposed below the cover glass 51, as already explained by means of FIG. 14. The embedding films 41 and 31 can optionally also carry the power rails, as explained by means of FIG. 14.

The embedding films 41 and 31 can be welded together to avoid the penetration of moisture. The solder connections between the front face contacts and the rear face contacts of the photovoltaic cells 1 and the power rails 30 and 40 can simultaneously be made during welding.

A rear face cover 52 borders on the embedding film 31. In some embodiments of the invention, the rear face cover can be transparent or translucent so as to create an unobstructed view through the photovoltaic module between the semiconductor substrates 10. Alternatively, the rear face cover 52 can have a colored design, which either stresses the geometric pattern of the semiconductor substrates 10 or hides the presence of the semiconductor substrates 10 from the viewer so as to create a homogeneous color impression of the photovoltaic module 5.

FIG. 20 shows a section of a third embodiment of a photovoltaic module according to the invention. Equal reference signs designate equal components of the invention, as a result of which the description is limited to the essential differences. The photovoltaic module according to FIG. 20 differs from the first embodiment according to FIG. 19 in that the rear face cover 52 is transparent and a decorative element 55 is arranged behind the rear face cover 52. The decorative element 55 can have a decorative design on both sides, e.g. in the form of a picture, a geometric pattern, a natural stone visual effect or a monochrome color design. The side of the decorative element 55 which faces the rear face cover 52 is visible in the intermediate spaces between the semiconductor substrates 10, as a result of which there is a major freedom as regards the façade design of a building. If the side of the decorative element 55, which faces away from the rear face cover 52, is visible during the normal operation of the photovoltaic module 5, it can have a different design, such that the user is offered a decorative sight of the photovoltaic module 5 from both sides.

In some embodiments of the invention, the decorative element 55 can be designed to be readily exchangeable, e.g. as a self-adhesive film or by Velcro fasteners. Due to this, it is possible to adapt the appearance of the photovoltaic module 5 to changing requirements.

FIG. 21 shows a section of a fourth embodiment of a photovoltaic module according to the invention. The embodiment according to FIG. 21 differs from the above described third embodiment in that the decorative element 55 is received in a further embedding film 32. As a result, the decorative element 55 protected against damage by mechanical action or moisture and the photovoltaic module 5 has a particularly sturdy structure.

FIG. 22 shows a section of a fifth embodiment of a photovoltaic module according to the invention. The fifth embodiment differs from the first embodiment in that photovoltaic cells 1a are arranged in a first plane and photovoltaic cells 1b are arranged in a second plane, the second plane being arranged behind the first plane in the direction of the incident light. A rear embedding film 31 is disposed between the photovoltaic cells 1a of the first plane and the photovoltaic cells 1b of the second plane. A further embedding film 32 is disposed between the photovoltaic cells 1b of the second plane and the rear face closure 52.

The photovoltaic cells 1a and 1b can be arranged in a striped pattern in the photovoltaic module 5. This leads to an angle-dependent absorption of sunlight and an also angle-dependent view through a window provided with the photovoltaic module 5. For example, the view can only be slightly impaired in an almost horizontal viewing direction whereas sunlight, which impinges on the photovoltaic module 5 from a higher position is absorbed in both planes since light which is incident through the intermediate spaces between the photovoltaic cells 1a, is absorbed by the photovoltaic cells 1b and is used for the electric energy production. In some embodiments, the photovoltaic cells 1a can be connected to a first inverter and the photovoltaic cells 1b can be connected to a second inverter.

FIG. 23 shows a sixth embodiment of a photovoltaic module according to the invention. The sixth embodiment differs from the fifth embodiment in that instead of the photovoltaic cells 1b of the second plane movable or rigid lamellas 17 are available by means of which the access of light into a room behind the photovoltaic module 5 and the view from this room can be controlled. In some embodiments, the lamellas 17 can be applied to the glazing 52 in the form of an opaque adhesive film or coating. FIG. 23 also explains how the photovoltaic module 5 can be part of a double or triple glazing which consists of the glass elements 53 and 54, the photovoltaic module 5 serving as an outermost glazing.

FIG. 23 also shows how obliquely incident sunlight 60 is absorbed by the photovoltaic cells 1. Light which gets through the intermediate spaces into the interior of the building can be absorbed by the lamellas 17.

FIG. 24 shows a section of an alternative embodiment of semiconductor substrates. The semiconductor substrate 10 according to FIG. 24 has a front face 101 and a rear face 102, as described above. Front face contacts 21 are arranged on the front face 101. Correspondingly, rear face contacts 22 are arranged on the rear face 102. Sunlight gets via the front face 101 into the semiconductor substrate 10 where it is absorbed, electron-hole pairs forming which can be tapped as electric voltage and electric current between the front face contact 21 and the rear face contact 22.

In order to avoid, or at least reduce, shadowing of the front face 101 by power rails, a bore 211 is located below the front face contact 21, said bore being filled or being conductively coated with a conductive material so as to connect the front face contact 21 to a contact element 210 on the rear face 102 of the semiconductor substrate 10. The contact element 210 can be connected to the power rail 40, as a result of which the two power rails 30 and 40 are arranged on the rear face 102 of the semiconductor substrate 10 and on the photovoltaic cell 1, respectively.

FIG. 25 shows a seventh embodiment of a photovoltaic module according to the invention. The seventh embodiment uses semiconductor substrates according to FIG. 24, as a result of which the first power rail and the second power rail 30 are both arranged on the bottom side 102 of the semiconductor substrate 10. Two photovoltaic cells 1a and 1b are shown again, wherein the photovoltaic module 5 can, of course, also have a larger number of photovoltaic cells and a larger number of power rails.

The first photovoltaic cell has three semiconductor substrates 10a, 10b and 10c, each having an approximately round basic form. The contact elements 210 and the rear face contacts 22 are arranged in such a way that the contact elements 210 are contacted by the first power rail 40 and the rear face contacts 22 are contacted by the second power rail 30. This leads to an electric parallel connection of the three semiconductor substrates 10a, 10b and 10c in the photovoltaic cell 1a.

The second photovoltaic cell 1b has a single semiconductor substrate 10d. In other embodiments of the invention, the number of semiconductor substrates can be larger or smaller in the respective cells. However, each photovoltaic cell advantageously has approximately an equal area of semiconductor substrates, as a result of which the voltage and current supplied by the photovoltaic cell are approximately equal. Of course, the respective form of the semiconductor substrates 10 can be different, as already described above.

As is shown in FIG. 25, the semiconductor substrate 10g is arranged in such a way that the contact element 210 is contacted with the second power rail 30 and the rear face contact 22 is contacted with the first power rail 40. This leads to a series connection of the first photovoltaic cell 1a and the second photovoltaic cell 1b.

The invention is, of course, not limited to the embodiments shown in the drawings. The above description should not be regarded as limiting but as explanatory. Features from different, above specified embodiments of the invention can be combined into further embodiments. The below claims should be comprehended in such a way that a stated feature is available in at least one embodiment of the invention. This does not rule out the presence of further features. If the claims and the above description define “first” and “second” features, this designation serves to distinguish between two features of the same kind without determining an order.

1. A photovoltaic cell, comprising a plurality of flat semiconductor substrates, each having a front face and a rear face, wherein at least one front face contact is arranged on the front face and at least one rear face contact is arranged on the rear face, wherein each of the semiconductor substrates forms a subarea of the photovoltaic cell and the semiconductor substrates are electrically connected to one another in parallel, wherein the semiconductor substrates are arranged at a distance from one another and at least two semiconductor substrates from the plurality of flat semiconductor substrates of a photovoltaic cell have a different shape and/or size and are arranged in a non-periodic pattern.

2. The photovoltaic cell according to claim 1, wherein said cell has a plurality of power rails, the longitudinal extensions of which extend along a first spatial direction and which enclose with the longitudinal extension of the front face contacts an angle of about 20° to about 90° or an angle of about 45° to about 90° or an angle of about 80° to about 90°.

3. The photovoltaic cell according to claim 2, wherein each power rail is electrically connected to every other power rail via at least one front face contact or at least one rear face contact.

4. The photovoltaic cell according to claim 1, wherein said cell has a plurality of power rails, and wherein the front face contacts are guided to the rear face of the semiconductor substrate via passages in the semiconductor substrates.

5. The photovoltaic cell according to claim 1, wherein said cell has a plurality of power rails, and wherein each power rail with the exception of at least one peripheral power rail is connected to at least two front face contacts or two rear face contacts of different semiconductor substrates.

6. The photovoltaic cell according to claim 1, wherein said cell has first power rails which are connected to the front face contacts and has second power rails, which are connected to the rear face contacts.

7. The photovoltaic cell according to claim 6, wherein the first power rails and the second power rails are arranged approximately parallel to one another, wherein the first and second power rails are offset to one another in a direction orthogonal to the longitudinal extension of the power rails.

8. The photovoltaic cell according to claim 1, wherein the plurality of flat semiconductor substrates consist of an equal or the same material.

9. The photovoltaic cell according to claim 1, wherein the plurality of flat semiconductor substrates consist of an equal or the same material and at least two semiconductor substrates have a coating of different color.

10. The photovoltaic cell according to claim 1, wherein said cell has a plurality of power rails, the photovoltaic cell further comprising segments, which are not electrically connected to the power rails, and/or further comprising segments, which are made from an insulating material and have at least one front face contact and/or at least one rear face contact, which is electrically connected to at least two power rails.

11. (canceled)

12. A photovoltaic module comprising a plurality of photovoltaic cells according to claim 1.

13. The photovoltaic module according to claim 12, wherein the plurality of flat semiconductor substrates of each photovoltaic cell has the same surface area.

14. The photovoltaic module according to claim 12, wherein the photovoltaic cells are serially connected to one another.

15. The photovoltaic module according to claim 12, wherein the photovoltaic cells are arranged in a first plane and in a second plane, the second plane arranged behind the first plane in the direction of the incident light.

16. A building or a façade element or a window element comprising the photovoltaic module according to claim 12.

17. Method for producing a photovoltaic cell, the method comprising the following steps:
producing a plurality of flat semiconductor substrates, each having a front face and a rear face, wherein at least two semiconductor substrates have a different shape and/or size and the plurality of flat semiconductor substrates are arranged in a non-periodic pattern,
applying at least one front face contact to the front face and producing at least one rear face contact on the rear face,
providing a plurality of second power rails, the longitudinal extensions of which extend along a first spatial direction,
applying the plurality of flat semiconductor substrates to the second power rails and electrically contacting the rear face contacts to the second power rails, wherein the semiconductor substrates are arranged at a distance from one another,
applying first power rails to the plurality of flat semiconductor substrates, wherein the first power rails extend approximately parallel to the second power rails and the longitudinal extension of the front face contacts enclose an angle of about 20° to about 90° or an angle of about 45° to about 90° or an angle of about 80° to about 90° with the power rails,
electrically contacting the front face contacts with the first power rails.

18. Method according to claim 17, wherein the cross-section of the power rails is partially embedded in an embedding film.
